(19) United States
(12) Patent Application Publication
(10) Pub. No.: US 2006/0118162 A1
(43) Pub. Date: Jun. 8, 2006

(54) Powering a vehicle and providing excess energy to an external device using photovoltaic cells

(75) Inventors: Max Saelzer, Davie, FL (US); Roger Messenger, Boca Raton, FL (US)

Correspondence Address: AKERMAN SENTERFITT, P.O. BOX 3188, WEST PALM BEACH, FL, 33402-3188, US

(73) Assignee: Florida Atlantic University, Boca Raton, FL (US)

(21) Appl. No.: 11/005,606

(22) Filed: Dec. 6, 2004

(51) Int. Cl. H01L 25/00

(52) U.S. Cl. 136/246; 136/244; 136/291

(57) ABSTRACT

A photovoltaic powering system is provided that includes a movable platform connected to a self-propelled vehicle. An array of one or more photovoltaic cells is carried by the movable platform. A platform movement mechanism carried by the vehicle moves the movable platform. A platform alignment module carried by the vehicle and connected to the platform movement mechanism causes the photovoltaic cells to be aligned relative to ambient sunlight. The one or more photovoltaic cells converts ambient sunlight to energy that is supplied to a battery carried by the vehicle to thereby recharge the battery if a charge associated with the battery is less than a predetermined threshold.

### BACKGROUND OF THE INVENTION

1. Field of the Invention

The present invention is related to the field of power generation, and, more particularly, to the generation of energy for powering a vehicle, as well as equipment carried by the vehicle, and for supplying excess energy to an external device or power grid.

2. Description of the Related Art

Electrical carts are vehicles whose relatively small size, low noise, and relatively low power consumption have long made them the vehicle of choice on many academic and business campuses as well as most golf courses throughout the world. In recent times, there have been attempts to power such vehicles with solar energy. These attempts have tended to center around devising arrays of photovoltaic cells that can be carried by such vehicles to provide a primary or secondary source of power.

A photovoltaic cell is an energy conversion device for converting solar energy into electrical energy. The typical photovoltaic cell comprises multiple layers of semiconductor materials fabricated to form a junction between adjacent layers of materials that have different electrical characteristics and one or more electrical contacts. Arrays of photovoltaic cells, sometimes termed photovoltaic arrays, have been used in a variety of settings for providing electrical power.

In general, the amount of power that can be generated by a photovoltaic array is a function of several variables. The variables that affect the amount of power generated by an array of photovoltaic cells include: (1) the intensity of the sunlight incident on the array; (2) the angle between the array and rays of sunlight incident thereon; (3) the surface area of the array; (4) the conversion efficiency of the photovoltaic cells that comprise the array; (5) the temperature of the array; and (6) the relationship between voltage and current of the array, termed its current-voltage characteristic, at the point at which the array is operated.

An inherent problem in powering any device using a photovoltaic array is that is often difficult to optimize the variables that determine how much power is generated by the array. For example, a fundamental problem relates to the first of the above-listed variables. The problem stems from the fact that a system designer can not predict when and how much sunlight will be available. But designing a system to influence even the other variables that can be directly influenced has proved to be almost as problematic. Nevertheless, a failure to optimize these variables means that the power generated by a photovoltaic array is likely to be less than the maximum that the photovoltaic array could otherwise provide.

The problem of optimizing these variables tends to be even more pronounced in the context of attempting to power an electric cart or similar type vehicle using a photovoltaic array. For example, in many settings, the need to use such a vehicle is not reduced by an absence of sunlight. It thus follows that on relatively overcast days there is an even more urgent need to affect the angle at which the limited number of rays of sunlight impinge upon the photovoltaic array. Achieving a more favorable alignment, however, is made all the more difficult by the fact that the vehicle may have to be stationed on a surface whose angle adversely affects the angle of incidence of sunlight on a photovoltaic array fixedly mounted on the vehicle.

Another inherent problem in controlling the variables that affect power conversion by the photovoltaic array relates to the current-voltage characteristic of the array. Absent some way to ensure that the photovoltaic array operates at the point that maximizes the array's power production, all other variables held constant, the array likely will generate less power than it could otherwise provide. Temperature of the array, moreover, can affect the current-voltage characteristic. Accordingly, since the operation of the vehicle and the environment in which it is operated are both likely to affect the temperature of the photovoltaic array, it is even more incumbent upon the designer to ensure that the array operates at a point that maximizes power production when all other variables are held constant.

Conventional vehicles that derive even some of their power from a photovoltaic array lack effective and efficient mechanisms for controlling many, if not all, of these variables. This means that such vehicles will typically be denied power than might otherwise be available were the variables more adequately controlled. Relatedly, the reduction of power relative to what otherwise might be generated limits the uses to which conventional vehicles can be used as well as the devices that can be powered off of these vehicles.

Additionally, conventional vehicles that use photovoltaic arrays to generate primary or supplemental power also typically lack an effective and efficient mechanism for converting excess energy into power that can be supplied to an external power grid. Power generated from a photovoltaic array carried by the vehicle but not otherwise used by the vehicle is accordingly lost before it can be put to a beneficial use.

### SUMMARY OF THE INVENTION

The present invention provides for the enhanced capture of solar energy using an array of photovoltaic cells carried by a self-propelled vehicle. The enhanced capture is a result of being able to affect key variables, such as the angle of incidence of sunlight on the photovoltaic cells and the energy transfer across an array-battery interface. The end result of capturing more solar energy is that relatively greater amounts of power can be generated by the array of photovoltaic cells. Moreover, this is achieved using elements that are not themselves stationary, but rather are carried with the self-propelled vehicle. Additionally, the enhanced capture of solar energy makes more likely the availability of excess energy that, in accordance with another object of the present invention, can be selectively supplied to an external electrical device or a power grid.

A vehicle according to one embodiment of the present invention can include a vehicle body, a vehicle propulsion mechanism for propelling the vehicle body over a surface, a vehicle motor carried by the vehicle body for driving the propulsion mechanism, and a battery carried by the vehicle body for supplying power to the vehicle motor. The vehicle, moreover, can include a photovoltaic powering system carried by the vehicle body. The photovoltaic powering system can convert captured solar energy into energy that can be used, for example, to recharge the vehicle-carried battery if a charge associated with the battery is less than a predetermined threshold. The photovoltaic powering system also can be used to power external electrical devices, according to another embodiment of the invention. In still another embodiment, excess energy generated by the photovoltaic powering system can be supplied to an external power grid.

A photovoltaic powering system, according to one embodiment of the present invention, can include an array of one or more photovoltaic cells carried by or mounted upon a movable platform connected to the vehicle. The photovoltaic powering system further can include a platform alignment module carried by the vehicle. The platform alignment module can connect to a platform movement mechanism and can cause the platform movement mechanism to optimally align the moveable platform relative to ambient sunlight. In an optimal alignment, the incidence of sunlight on the array on photovoltaic cells is orthogonal, or normal, to a top surface of each photovoltaic cell mounted on the moveable platform connected to the vehicle.

Yet another aspect of the present invention is a combined docking-and-powering station for a plurality of vehicles. The combined docking-and-powering station can include a plurality of docking stations and an external battery bank connected to the plurality of docking stations. The combined docking-and-powering station can be used for selectively exchanging power between a photovoltaic array, the external battery bank, and a power grid connected to the external battery bank.

Still another embodiment of the present invention is a method of generating and supplying power using solar energy. The method can include automatically aligning an array of one or more photovoltaic cells relative to ambient sunlight, the array being connected to a self-propelled vehicle. The method further can include converting the ambient sunlight to usable energy, and supplying the usable energy to a battery carried by the vehicle to thereby recharge the battery if a charge associated with the battery is less than a predetermined threshold.

A method according to an additional embodiment of the present invention includes electrically connecting a plurality of photovoltaic arrays carried by vehicles to a combined docking-and-powering station, the docking-and-powering station including a plurality of vehicle docking stations and an external battery bank comprising a plurality of interconnected batteries that are electrically connected both to the plurality of docking stations and to a separate power grid. The method can further include selectively conveying power among the photovoltaic arrays, the external battery bank, and the power grid.

### BRIEF DESCRIPTION OF THE DRAWINGS

There are shown in the drawings, embodiments which are presently preferred, it being understood, however, that the invention is not limited to the precise arrangements and instrumentalities shown.

FIG. 1 is a schematic diagram of an electrical cart that includes a photovoltaic powering system, according to one embodiment of the present invention.

FIG. 2 is a more detailed schematic diagram of selected elements of the photovoltaic powering system of FIG. 1, according to another embodiment of the present invention.

FIG. 3 is a schematic diagram of selected elements of a photovoltaic powering system, according to another embodiment of the present invention.

FIG. 4 is a schematic diagram of selected elements of a photovoltaic powering system, according to still another embodiment of the present invention.

FIG. 5 is a plot of power versus voltage at a photovoltaic array-battery interface according to yet another embodiment of the present invention.

FIG. 6 is a schematic diagram of selected elements of a photovoltaic powering system, according to still another embodiment of the present invention.

FIG. 7 is a schematic diagram of an electrical cart that includes a photovoltaic powering system, according to another embodiment of the present invention.

FIG. 8 is a schematic diagram of a combined docking-and-powering station, according to yet another embodiment of the present invention.

FIG. 9 is a flowchart illustrative of a method aspect of the present invention.

FIG. 10 is a flowchart illustrative of another method aspect of the present invention.

FIG. 11 is a flowchart illustrative of yet another method aspect of the present invention.

FIG. 12 is a flowchart illustrative of still another method aspect of the present invention.

FIG. 13 is a flowchart illustrative of an additional method aspect of the present invention.

FIG. 14 is a flowchart illustrative of still another method aspect of the present invention.

FIG. 15 is a flowchart illustrative of yet another method aspect of the present invention.

### DETAILED DESCRIPTION OF THE INVENTION

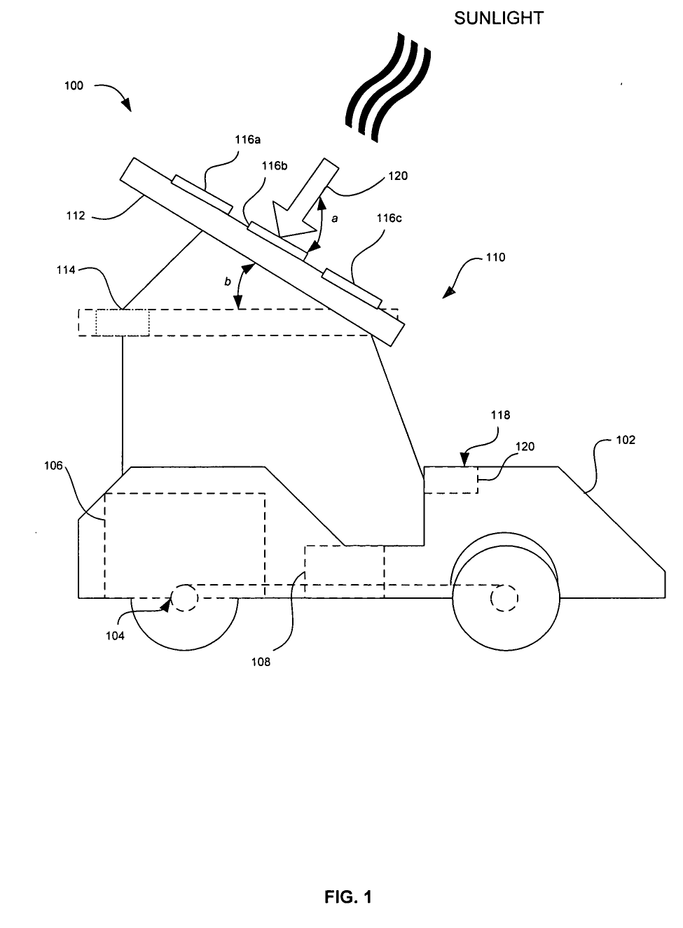

FIG. 1 is a schematic diagram of a self-propelled vehicle 100 according to one embodiment of the present invention. The vehicle 100 illustratively includes a vehicle body 102 and a vehicle propulsion mechanism 104 for propelling the vehicle body over a surface. The vehicle propulsion mechanism 104 is illustratively driven by a vehicle motor 106 carried in or mounted on the vehicle body 102. The vehicle motor 106 is illustratively powered by a battery 108, which is also carried in or mounted on the vehicle body 102. As further illustrated, the vehicle 100 includes a photovoltaic powering system 110 carried by the vehicle body 102.

The size and shape of the vehicle body 102 can vary depending on the function that the vehicle 100 performs and/or the environment in which it is used. For example, the vehicle 100 can be used to transport one or more individuals within a campus or recreational environment, such as a university campus or a golf course, in which case the vehicle body 102 can be sized to carry a driver and at least one passenger as well as a limited amount of paraphernalia, such as luggage, maintenance equipment, golf clubs, or other sporting gear. Alternatively, the vehicle 100 can be used, for example, as a remotely controlled platform for performing various functions, such as carrying out surveillance or handling explosives in a military or construction environment. For carrying out such functions, the vehicle body 102 can be of a relatively smaller size while also being made more sturdy through, for example, the addition of various types of structural reinforcements within the vehicle body.

Similarly, the vehicle propulsion mechanism 104 can vary according to the environment in which and the purpose for which the vehicle 100 is used. For example, if the vehicle is used in a campus or recreation setting, the vehicle propulsion mechanism can include wheel-bearing axes connected to a drive shaft. Alternatively, if the vehicle is used in a military or construction environment, a pair of treaded endless belts can be substituted for wheels as part of the vehicle propulsion mechanism 104.

The vehicle motor 106 can be, for example, a 36-volt traction motor or a 48-volt traction motor. Again, the size of the vehicle motor 106 can vary according to the function the vehicle 100 is to perform and/or the environment in which it is to be used. The battery 108 can comprise a plurality of batteries, defining a battery pack. For a number of uses and in a number of settings, a 36-volt traction motor powered by 36-volt batteries, or a 48-volt traction motor powered by 48-volt batteries is adequate.

The photovoltaic powering system 110 illustratively includes a movable platform 112 connected to the vehicle body and comprising an array 116 of at least one photovoltaic cell 116a-c. More particularly, one or more photovoltaic cells 116a-c can be integrally formed with or mounted to the moveable platform 112 comprising the array 116. If, as illustrated, the movable platform 112 is positioned above the vehicle body 102, it can serve the dual function of also providing a roof or covering. A platform movement mechanism 114 is mechanically connected to the movable platform 112 to thereby effect various movements and changes in position of the platform.

Only three exemplary photovoltaic cells are shown in the figure, and their relative sizes are exaggerated. It will be readily understood by one of ordinary skill in the art, however, that an actual array can include many more photovoltaic cells and that the size of the photovoltaic cells can be much smaller than the exemplary three cells shown. Indeed, the array 116 can comprise several hundred photovoltaic cells. As will also be readily appreciated by one of ordinary skill in the art, the photovoltaic array converts ambient sunlight into energy. As explained below, the energy can be used for multiple purposes, including to recharge the battery 108.

The photovoltaic powering system 110 also illustratively includes a monitor-and-control circuit 118 carried in or mounted to the vehicle body 102 for monitoring and controlling one or more functions of the photovoltaic powering system, as explained herein. According to one embodiment, the monitor-and-control circuit 118 comprises a processor, such as a microprocessor having a central processing unit (CPU) and local memory connected by a data bus, as will be readily understood by one of ordinary skill in the art.

The monitor-and-control circuit 118 illustratively contains a platform alignment module 120 that connects to the platform movement mechanism 114. The platform alignment module 120 can comprise a set of software-based instructions configured to run on a processor. Alternately, the platform alignment module 120 can comprise one or more dedicated hardwire circuits. According to yet another embodiment, the platform alignment module 120 can comprise a combination of software-based instructions and dedicated circuitry. As explained in greater detail below, the platform alignment module 120 causes the platform movement mechanism 114 to align the moveable platform 112 relative to ambient sunlight; in an optimal position, the moveable platform 112 is aligned at an angle, a, such that a vector representation 120 of rays of incident sunlight is orthogonal to the surfaces of the photovoltaic cells 116a-c integrally formed with or mounted on a surface portion of the moveable platform. Although sometimes the optimal position may not be attainable, a desired angle that increases the intensity of the ambient sunlight incident upon the photovoltaic cells 16a-c relative to other possible angles can be achieved.

The platform movement mechanism 114 can be implemented using one or more of several different mechanized assemblies. As illustrated, the angle a can be achieved, for example, by the platform movement mechanism 114 raising the backend of the moveable platform 112 relative to the front end. To effect the movement, the platform movement mechanism 114 can comprise a motor-driven mechanism such as, for example, a DC motor that drives a system of gears (not shown) and a threaded rod (not shown), wherein the threaded rod is configured to operate a scissors mechanism (not shown) that converts a rotational torque into transverse forces and then into vertical forces. More preferably, the threaded rod is configured to operate a cylindrical mechanism that converts rotational torque directly into vertical forces for changing the angle of the moveable platform 112.

The platform movement mechanism 114 can alternatively be implemented with other mechanized assemblies, which can be used to effect angling in different directions relative to the vehicle body 102. For example, with an alternate mechanized assembly, the front end of the moveable platform 112 can be raised. Similarly, various other mechanized assemblies can raise one or both sidewise edges of the moveable platform. Indeed, by implementing the platform movement mechanism 114 using different mechanized assemblies, various combinations of such edgewise movements can be effected. Thus, the moveable platform 112 can be made to pivot in any direction from a horizontal plane relative to the top of the vehicle body 102, and to thereby achieve the desired angle regardless of the direction from which the ambient sunlight arrives at the vehicle body 102.

According to still another embodiment, the moveable platform 112 can comprise a rotatable base. The rotatable base can be configured to rotate through at least 180 degrees in a horizontal plane. Additionally, at least one edge of the moveable platform 112 can be elevated relative to the horizontal plane so as to be orthogonal or approximately perpendicular to rays of sunlight that may emanate from different directions relative to the vehicle 100.

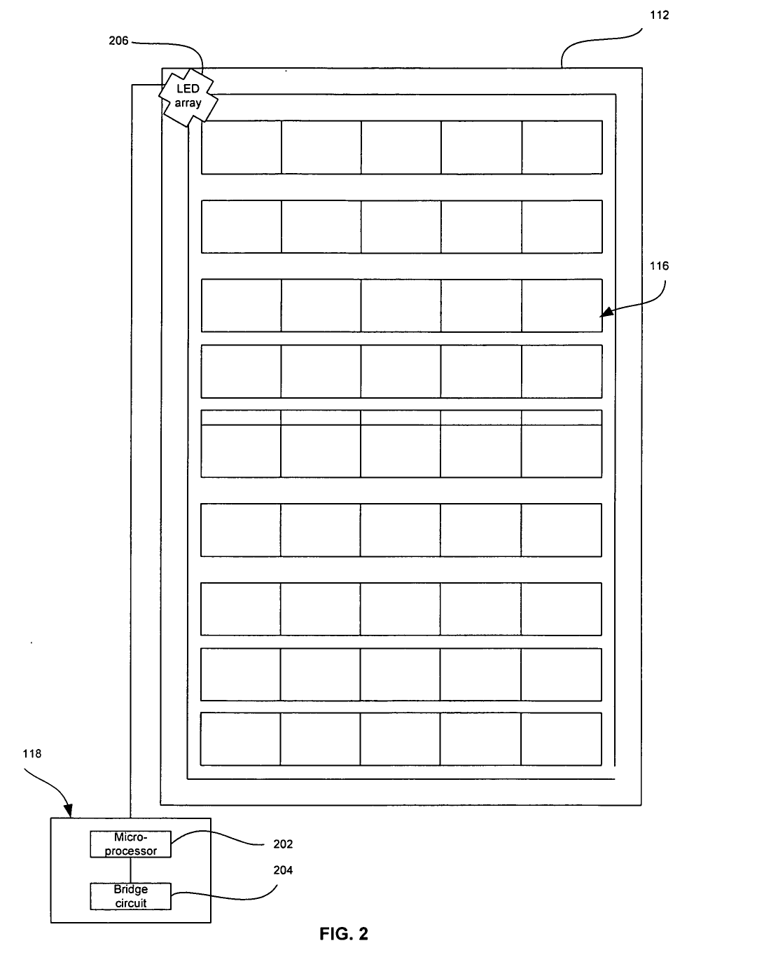

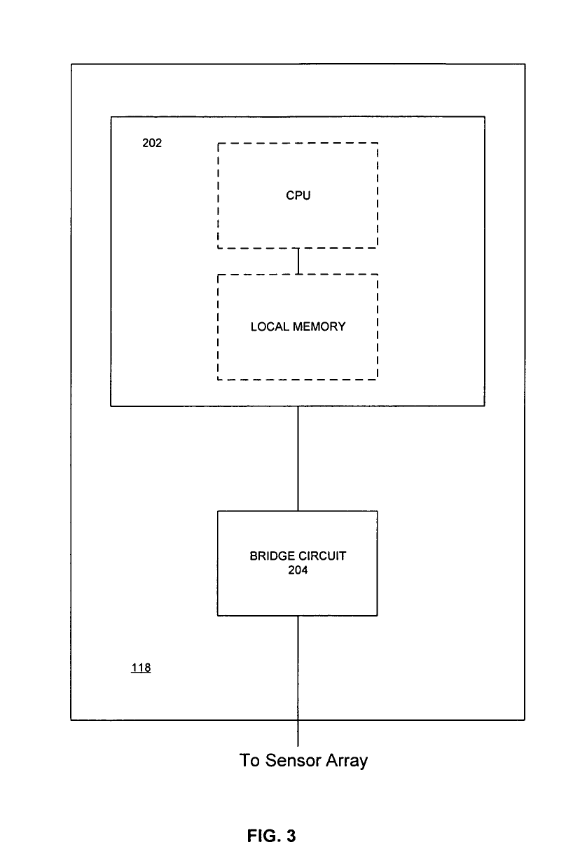

Referring additionally to FIGS. 2 and 3, in one embodiment, the monitor-and-control circuit 118 comprises a processor 202, such as a microprocessor, and a bridge circuit 204 electrically connected to the processor 202. The platform alignment module 120 can comprise a set of software-based instructions configured to run on the processor 202. Alternatively, the platform alignment module 120 can comprise one or more dedicated hardwired circuits connected to or contained within the processor 202. The platform alignment module 120, according to still another embodiment, can comprise a combination software based-instructions configured to run on the processor 202 as well as one or more dedicated hardwired circuits connected with or contained within the processor.

The bridge circuit 204 electrically connected to the processor 202 illustratively connects to a sensor array 206 positioned atop the moveable platform 112 adjacent to the plurality of photovoltaic cells that define the photovoltaic array 116 and that are integrally formed with or mounted to the platform. The platform alignment module 118 determines the desired angle based upon sensory data generated by the sensor array 206 and supplied via the bridge circuit 204 to the processor 202.

The sensor array 206 can be implemented, for example, with a plurality of photodiodes or light emitting diodes (LEDs) arranged in a quadrature configuration. The sensor array 206 conveys a series of differential control signals to the electronic bridge circuit 204. The electronic bridge circuit 204, in turn, conveys a series of indicator signals to the processor 202 indicating the sensed position of the sun. Responsive to the indicator signals, the processor 202 generates a series of control signals that are conveyed to the platform movement mechanism 114. In response to the control signals, the platform movement mechanism 114 effects the alignment of the moveable platform 112 at the desired angle relative to the incidence of sunlight upon the photovoltaic array 116.

For example, if the platform movement mechanism 114 is implemented using the threaded rod driven by a DC motor described above, then the control signals conveyed by the processor 202 will cause the threaded rod to rotate in either a clockwise or counterclockwise direction depending on whether an edge of the moveable platform 112 is to be elevated or lowered so as to achieve the desired angle.

Whether implemented in software-based instructions configured to run on the processor 202 and/or dedicated hardwired circuitry connected with or incorporated in the processor, the platform alignment module 120 causes the platform movement mechanism 114 to align the moveable platform 112 relative to ambient sunlight as described above. According to still another embodiment, the platform alignment module 120 encompasses an additional feature, that of determining the intensity of ambient sunlight incident upon the photovoltaic array 116. As will be readily understood by one of ordinary skill in the art, this feature can be accomplished by configuring the sensor array 206, or alternately, adding an additional sensing device, such as a photodector, that generates a voltage or current that is proportional to the photons or light energy that impinge upon the area in which the photovoltaic array 116 is situated.

If the intensity of ambient sunlight is too low, the energy expenditure in driving the platform movement mechanism 114 can exceed the additional solar energy captured by the photovoltaic array 116 by further alignment. That is, there is trade-off between the additional energy expended and the additional energy captured that is directly related to the intensity of the sunlight available to the photovoltaic array 116. Accordingly, the platform alignment module 120 is preferably configured to operate in a standby mode when the intensity of ambient sunlight is less than a predetermined threshold, the threshold being based on the trade-off between energy expended and energy captured with an alignment of the moveable platform 112.

When operating in a standby mode, the platform alignment module 120 can continue to assess the availability of ambient sunlight for capture by the photovoltaic array 116. This can be accomplished by the platform alignment module 120, using a photodetector or other additional sensing device, intermittently measuring the intensity of sunlight incident upon the area in which the photovoltaic array 116 is situated. Sunlight intensity can be sampled at regular or irregular intervals, according to a pre-designed scheme or at random. When the intensity of ambient sunlight exceeds the predetermined threshold based upon the energy trade-off already described above, the platform alignment module 120 ceases to operate in a standby mode and reverts to tracking the ambient sunlight relative to the vehicle 100 so as to causes the platform movement mechanism 114 to align the moveable platform 112 relative to ambient sunlight as already described.

After the platform alignment module 120 reverts to tracking the ambient sunlight, the platform alignment module determines the position of the sun relative to the vehicle 100. Accordingly, if the sun is determined to be in front of the vehicle 100, then a desired angle of incidence of sunlight can be achieved by the platform alignment module 120 causing the platform alignment module to raise the back edge of the moveable platform 112. Alternatively, if the sun is positioned behind the vehicle 100, then the platform alignment module 120 can cause the platform alignment module to raise the front edge of the moveable platform 112. If instead the sun is on the starboard side of the vehicle, the platform alignment module 120 can cause the port edge of the moveable platform 112 to be elevated. Similarly, if the sun is on the port side of the vehicle 100, then the platform alignment module 120 can cause the starboard edge of the moveable platform 112 to be elevated.

Once a desired angle is attained for the moveable platform 112 relative to ambient sunlight, the platform alignment module 120 can begin operating in a timing mode. In the timing mode, the platform alignment module 120 intermittently tracks the position of the sun. This can be accomplished by periodically sampling readings generated by the sensor array 206. The sampling can be performed at regular or irregular time intervals according to a predetermined schedule, at random intervals, or according to some modified scheme based, for example, on weather conditions such as the prevailing cloudiness of the sky. The scheme, moreover, can be preset, or, alternately, it can be newly set according to a particular set of user specifications. If the sun is tracked periodically rather than continuously, there is no need to continuously re-align the moveable platform 112 by continuously driving the platform alignment mechanism 114. This can effect an energy savings. Additionally, the rate of sampling can be chosen so as to reflect a desired trade-off between the additional energy captured through more frequent alignments versus the increased energy expended needed for more frequently aligning the moveable platform 112.

Accordingly, as described, the software-based instructions configured to run on the processor 202 and/or the hardwired circuitry connected with or contained in the processor for implementing the platform alignment module 120 can be based upon an algorithm according to which electronic signals generated in the sensor array 206 are intermittently sampled. It is by virtue of the sampling of these signals that the platform alignment module 120 can change the alignment of the moveable platform 112 in response to changes in position of one or both of the sun and/or the vehicle 100.

The algorithm, moreover, can comprise a closed-loop control algorithm whose subroutines keep the platform alignment module 120 from performing an endless search routine. Such an endless search routing might otherwise occur when clouds or shade fall over the photovoltaic array 116 and prevent a minimal amount of sunlight from reaching the photovoltaic array. This prevents the wasteful expenditure of the vehicle's stored energy that would otherwise occur with continued angle adjustments in a futile attempt to increase the amount of sunlight impinging on the photovoltaic array 116.

According to yet another embodiment, the platform alignment module 120 is capable of detecting when an angle, b, of the moveable platform 112 relative to the top of the vehicle body 102 constitutes a critical tilt angle. As used herein, a critical angle denotes an angle beyond which the moveable platform 112 should not be tilted whenever the vehicle is being propelled over a surface.

According to still another embodiment, the platform alignment module 120 is configured to detect when a driver is in the vehicle driver seat. For example, the platform alignment module 120 can include a sensor positioned in or adjacent the driver seat of the vehicle to sense whether or not the driver seat is occupied. When the driver seat is not occupied, it can be assumed that the vehicle 100 is stationary. Accordingly, the platform alignment module 120 can initiate the alignment of the moveable platform 112 when the driver seat is unoccupied. When the driver seat is occupied, however, it can be assumed that the vehicle is moving, or about to move, over a surface. Therefore, when the driver seat is occupied, the platform alignment module 120 can cause the platform movement mechanism 114 to position the moveable platform 112 in a flat or nearly flat position relative to the top of the vehicle body 102 so that the vehicle can be propelled more conveniently and efficiently over a surface.

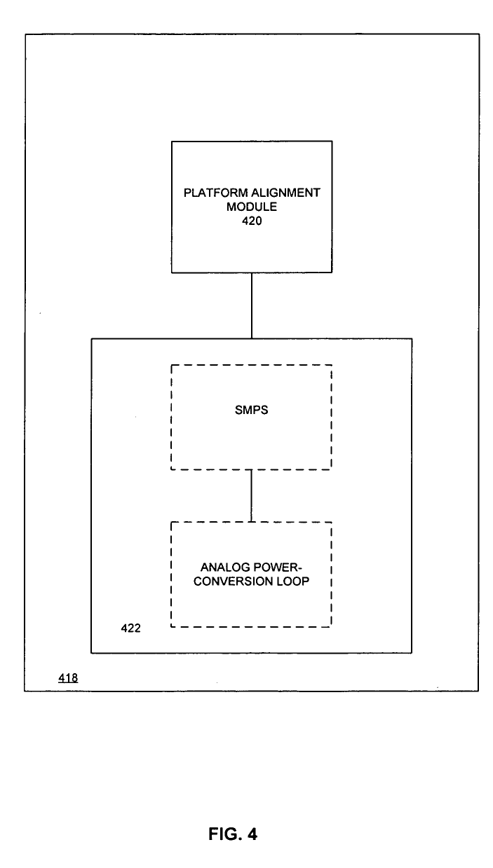

As illustrated in FIG. 4, the photovoltaic powering system 110 according to another embodiment comprises a monitor-and-control circuit 418 that includes both a platform alignment module 420 and a power tracking module 422. As will be readily understood by one of ordinary skill in the art, the power tracking module 422 can be implemented by combining a high-efficiency circuit, such as a switch mode power supply (SMPS) circuit, with an analog power-conversion loop. Functionally, the power tracking module 422 controls the transfer of energy from the photovoltaic array 116 to the battery 108, taking into account varying operating conditions in terms of the voltage, current, and insolation (i.e., a standardized sunlight intensity of 1 kW/m2) parameters associated with the array-battery interface.

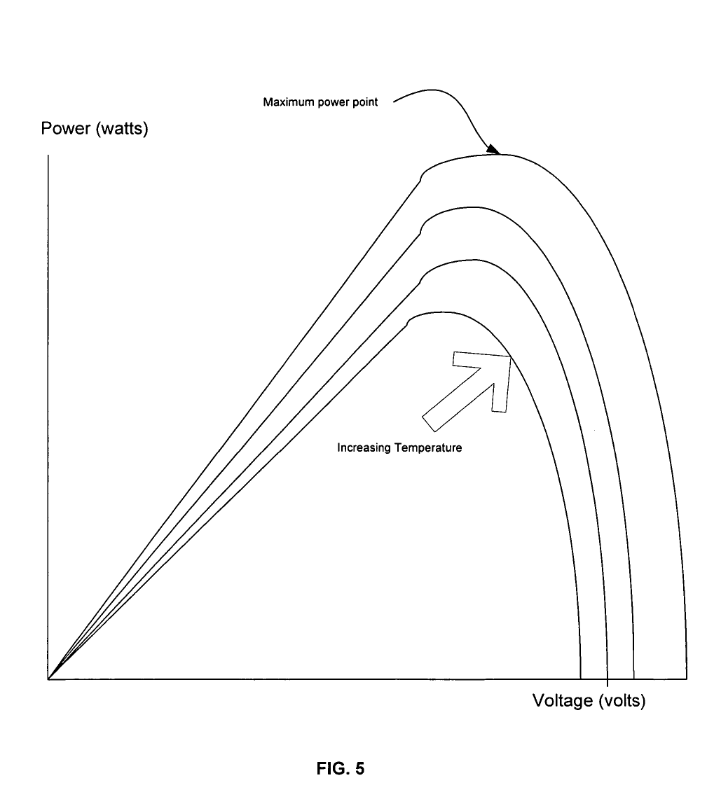

Referring additionally to FIG. 5, the power generated by the photovoltaic array 116 versus the array voltage is illustrated for various temperature levels of the array. The power tracking module 422 controls energy transfers across the array-battery interface so that the photovoltaic array 116 operates at or close to a maximum power point 121. Operating at the maximum power point 121, the photovoltaic array 116 delivers an optimal amount of power to the battery 108.

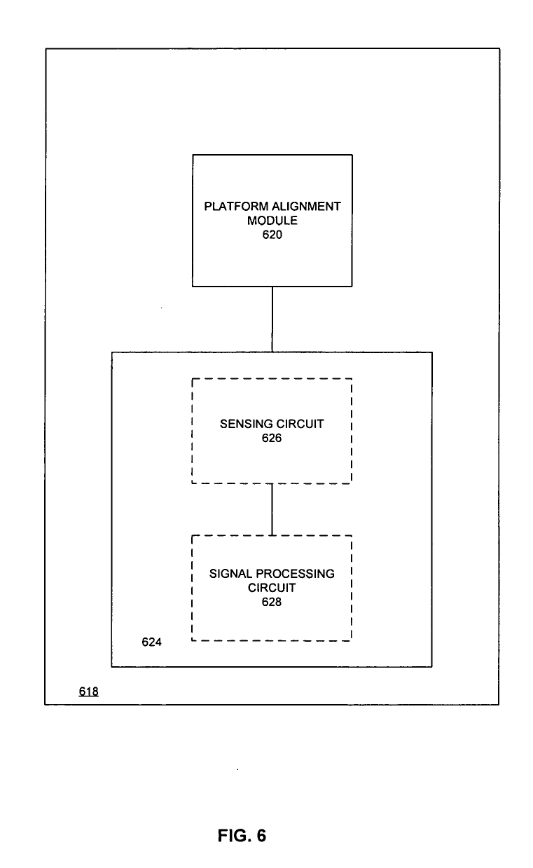

FIG. 6 illustrates still another embodiment according to which the photovoltaic powering system 10 comprises a monitor-and-control circuit 618 that includes a performance monitoring module 624. The performance monitoring module 624 monitors the charge on the battery 108 and can be implemented, for example, with a sensing circuit connected to the battery 108 for sensing a voltage or current of the battery and a signal processing circuit connected to the sensor for processing a signal based upon the sensed voltage or current. Alternately, the performance monitoring module 624 can be implemented with a set of software instructions configured to run on a processor, such as a microprocessor, for processing a signal provided by a sensor connected to the battery 108. The performance monitoring module 624 can monitor the voltage of the battery 108, or, more preferably, a current through the battery. More particularly, the performance monitoring module 624 can comprise software-based instructions and/or dedicated circuitry for integrating a signal with respect to time, the signal representing an electrical current through the battery.

In yet another embodiment, the performance monitoring module 624 connects to the photovoltaic array 116 and monitors the energy delivered by the array. As explained below, energy can be delivered from the photovoltaic array 116 not only to the battery 108 but also to an external electric device or a power grid, and, accordingly, the performance monitoring module 624 can monitor the energy delivered to the battery 108 and/or an external electric device or power grid. The performance monitoring module 624 can measure the instantaneous power delivery, or, alternately, a cumulative energy delivery from the photovoltaic array 116 to the battery 108, an external electric device, and/or a power grid. According to still another embodiment, the performance monitoring module 624 monitors power used by the vehicle motor 106 and/or an external electrical device.

According to still another embodiment, the performance monitoring module 624 is configured to download to an electronic memory device (not shown) one or more variable or parameter values associated with the charge on the battery 108 and/or the energy delivered to an external electrical device or power grid. The associated variable or parameter values pertain to energy conversions and transfers effected by the photovoltaic powering system 110. By storing the associated variable or parameter values in an electronic memory device, the performance monitoring module 624 is able to construct one or more performance profiles corresponding to one or more of the various functions performed by the photovoltaic powering system 110 and described above. The one or more performance profiles, constructed from stored data amassed over time, can be used to assess how well the photovoltaic powering system 110 performs over time in terms of using the photovoltaic array 116 to convert and transfer energy for re-charging the battery 108 and/or delivering energy to an external electrical device or power grid.

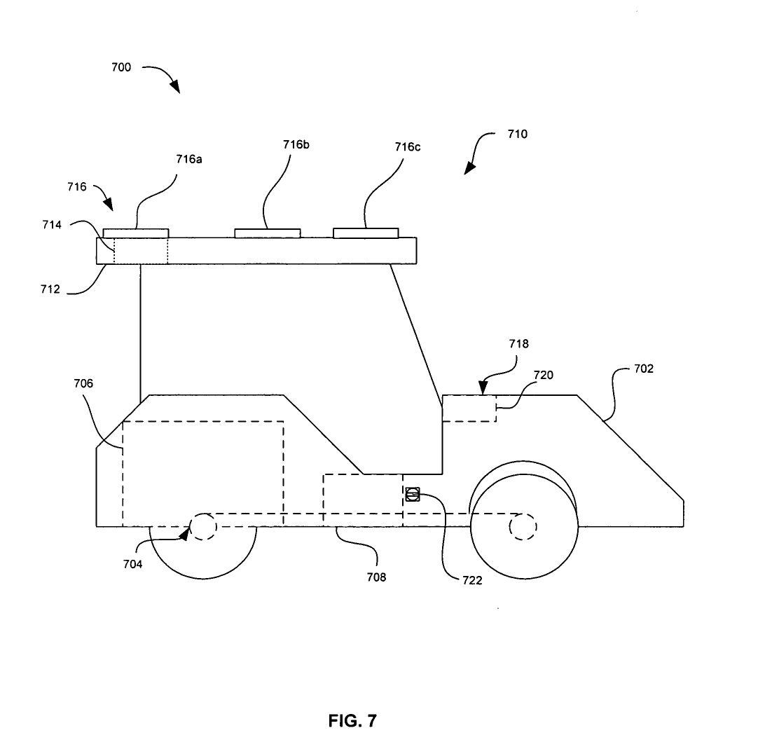

FIG. 7 is a schematic diagram of a self-propelled vehicle 700 according to another embodiment of the present invention. The vehicle 700 illustratively includes a vehicle body 702 propelled by a vehicle propulsion mechanism 704, which, in turn is driven by a vehicle motor 706 that is powered by a battery 708. The vehicle 700 also includes a photovoltaic powering system 710 carried by the vehicle body 702, as well as an excess power delivery device 722 also carried by or otherwise mounted to the vehicle body.

The photovoltaic powering system 710 illustratively includes a movable platform 712 positioned adjacent the vehicle body 702, a platform movement mechanism 714 for moving the platform, a photovoltaic array 716 containing at least one photovoltaic cell 716a-c, and a monitor-and-control circuit 718 for monitoring and controlling one or more functions of the photovoltaic powering system.

The excess power delivery device 722 can connect to the battery 708 and to an external electrical device and/or a power grid for providing a conduit through which power can be delivered to the external electrical device and/or power grid. More particularly, the excess power delivery device 722 can be a controllable DC outlet that is monitored and controlled by the monitor-and-control circuit 718. Power can be delivered from the battery 708 and/or the array 716. Thus, according to one embodiment, the controllable DC outlet is automatically controlled to ensure that power is delivered from the photovoltaic array 716 through the battery to the controllable DC outlet where it can be received by the external electrical device and/or power grid.

Alternatively, the DC outlet can be automatically and/or manually controlled to deliver power from the battery 708 on demand. This latter feature allows the battery 708 to be used, for example, to supply power in the event of an unanticipated emergency unrelated to the ordinary use of the vehicle 700, such as a general power outage. In more typical situations, wherein the vehicle is used, for example, for maintenance work or grounds keeping, power can be supplied for running equipment such as hand-held power tools, electric hedgers, and similar electrical devices.

According to yet another embodiment, the excess power delivery device 712 further comprises an on-board electrical inverter. By virtue of inclusion of the inverter, the excess power delivery device 712 is able to convert a DC current to an AC current. This permits the delivery of power via the excess power delivery device 712 to a wider array of electrical devices. Moreover, since many power grids are only adapted to receive AC current, this permits delivery of power to any grid at virtually any location.

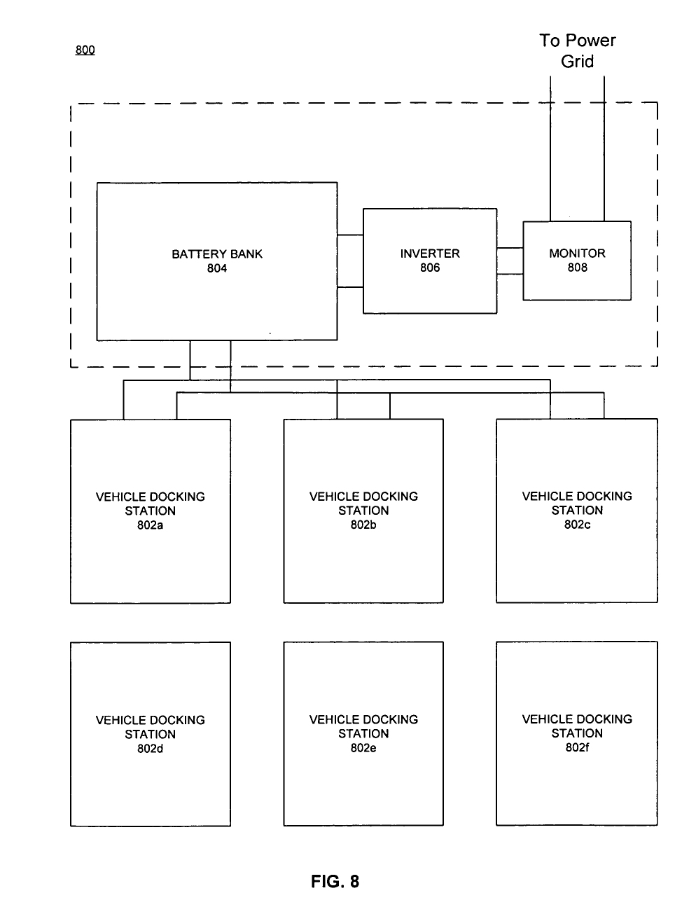

As illustrated in FIG. 8, another embodiment of the present invention comprises a combined docking-and-powering station 800 for a plurality of vehicles. The station 800 illustratively includes a plurality of docking stations 802a-f and an external battery bank 804 comprising a plurality of interconnected batteries, the external battery bank connected between the plurality of docking stations 802a-f and an external power grid. Each one of the docking stations 802a-f is specifically configured to electrically connect the external battery bank 804 to a vehicle, the vehicle being powered either solely by a vehicle-mounted or by a vehicle-mounted battery is itself periodically recharged by a vehicle-mounted photovoltaic array.

The external battery bank 804 provides a charging current to a vehicle when the vehicle is connected to one of the docking stations 802a-f and the battery that powers the vehicle is discharged. Alternately, if the external battery bank 804 is discharged, then the battery bank receives a charging current from each vehicle connected to one of the docking stations 802a-f and having a charged battery. Moreover, whenever the external battery bank 804 is fully charged, energy transferred to the external battery bank from each vehicle electrically connected to one of the plurality of docking stations 802a-f is relayed from the external battery bank to the power grid.

Thus, according to one embodiment, the combined docking-and-powering station 800 further includes an inverter 806 that converts a DC current to an AC current. The inverter 806 enables the combined docking-and-powering station 800 to supply excess energy to a power grid that comprises an AC-based power system. Alternately, when, the external battery bank 804 is not fully charged, energy can be obtained from the power grid connected to the combined docking-and-powering station 800 in order to restore the external battery bank to a fully charged condition. A monitor 808 optionally connects to the inverter 806 to monitor the transfers between the external battery bank 804 and the power grid.

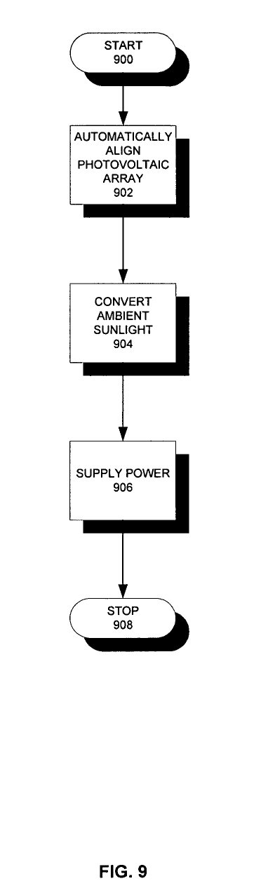

FIG. 9 is flowchart that illustrates a method aspect of the present invention. The method 900 includes automatically aligning, at step 902, a photovoltaic array connected to a self-propelled vehicle and comprising at least one photovoltaic cell relative to ambient sunlight. Optimally, the photovoltaic array is aligned so that the angle of incidence of the sunlight is normal to a top, active surface of the at least one photovoltaic cell. In accordance with the method, if a ninety-degree angle is not attainable, the photovoltaic array is aligned at an angle relative to the sunlight that increases the intensity of the sunlight incident upon the photovoltaic cells over other angles that could otherwise be attained.

The method 900 continues with the ambient sunlight incident upon the photovoltaic array being converted at step 904 into an energy form that can be used to recharge a battery, such as a DC battery carried by the vehicle. At step 906, the usable energy is supplied to a battery carried by the vehicle to thereby recharge the battery if a charge associated with the battery is less than a predetermined threshold. The method concludes at step 908.

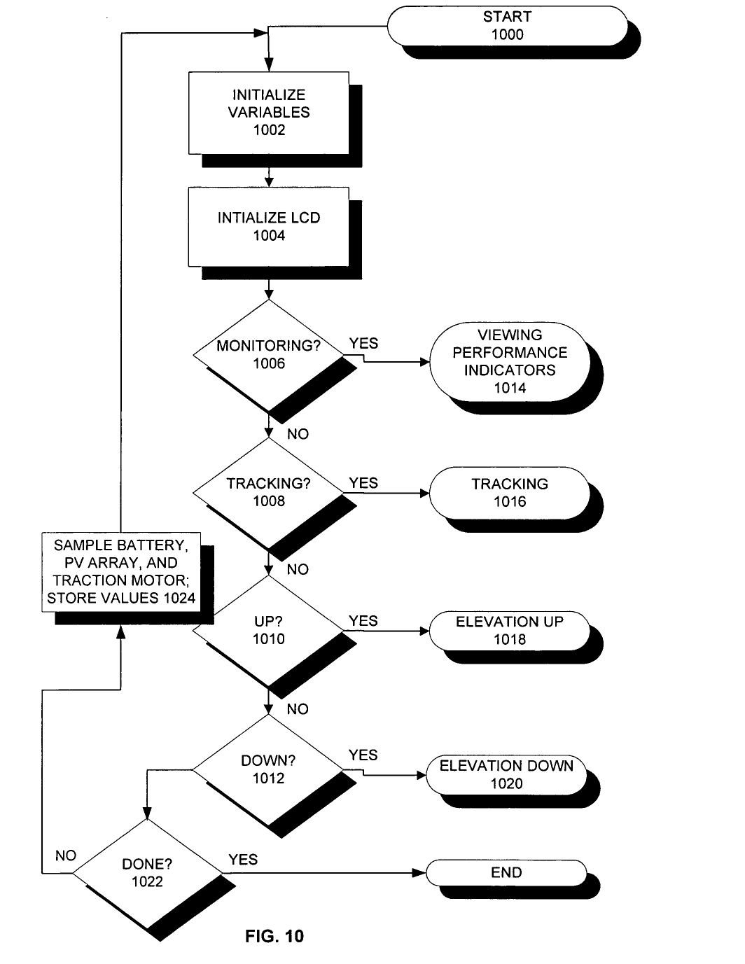

Another method aspect of the invention is illustrated by the flowchart in FIG. 10. The method 1000 is directed to monitoring and controlling the conversion and transfer of energy for powering a motor-driven vehicle using a re-chargeable battery and a photovoltaic array. A set of monitoring variables is initialized at step 1002, each of the variables pertaining to the monitoring and control of energy conversions and transfers. A liquid crystal display (LCD) for displaying some or all of the variables is initialized at step 1004. In steps 1006-1012, a user is given an option of choosing one of four different procedures to pursue according to the method. The options presented to the user include viewing a series of performance indicators on the LCD at step 1014, tracking a position of the sun relative to the vehicle at step 1016, elevating the photovoltaic array at step 1018, or lowering the photovoltaic array step 1020. For ease of presentation and understanding the exemplary steps of elevating and lowering the photovoltaic array are referred to here. Based on the discussion thus far, however, it will be apparent that other alignment steps can be added to or substituted for the exemplary steps.

The procedure then either continues at step 1022 or ends at step 1024. If the procedure continues, then, at step 1026, at least one variable value associated with at least one of a battery for powering the vehicle, the photovoltaic array, and a motor such as a traction motor is determined. The value or values determined are stored for subsequent use if the procedure continues. The value or values can be stored in an electronic memory device, for example.

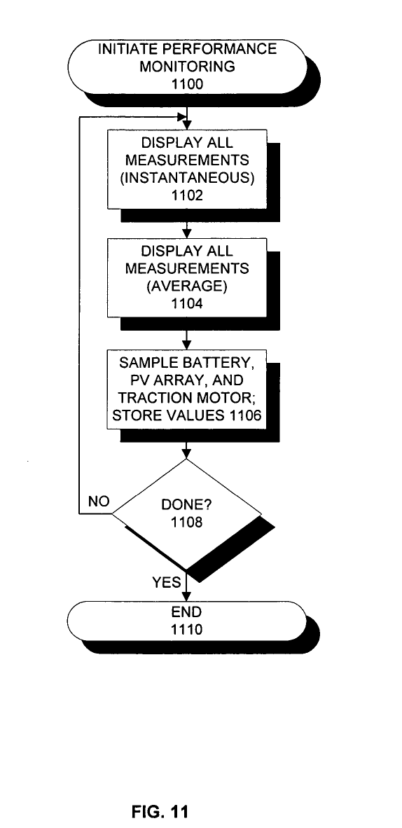

FIG. 11 provides a flowchart illustrating the steps of a procedure for displaying and monitoring values associated with energy conversions and transfers performed in connection with powering a motor-driven vehicle using a re-chargeable battery and a photovoltaic array. The initiation of the procedure at step 1100 results in the display of instantaneous measurements at step 1102 and/or the display of average measurements at step 1104. The measurements, more particularly, are of parameters or variables associated with at least one of the battery, the photovoltaic array, and the motor. The measurements can provide one or more indications of the performance of the energy conversions and transfers. One or move of these variables is re-sampled and stored in memory at step 1106. A user then has the option, at step 1108 of continuing or ending the procedure. If the user opts to continue, then the stored values are again displayed as the sequence repeats, or else, the procedure ends at step 1110.

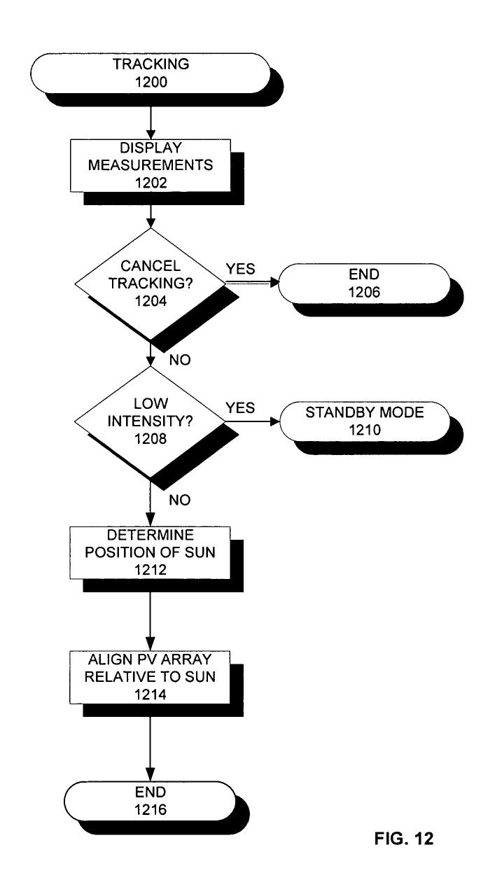

FIG. 12 provides a flowchart illustrating the steps of a tracking procedure used in connection with powering a motor-driven vehicle using a re-chargeable battery and photovoltaic array. The method is directed to tracking the position of the sun relative to the vehicle and aligning the photovoltaic array relative to ambient sunlight to thereby increase the capture of solar energy from the sun. At step 1202, one or more values associated with at least one of the battery, the photovoltaic array, and the motor are displayed. The user, at step 1204, is given the option of canceling the tracking procedure or continuing. The procedure ends at step 1206 if the user opts to discontinue.

If the user opts to continue, however, the intensity of available sunlight is determined at step 1208. Based upon the determined intensity of sunlight, a determination is automatically made as to whether the energy expenditure needed for realigning the photovoltaic array is greater than or less than the additional solar energy that can be captured by realigning the photovoltaic array. If the trade-off is unfavorable, then at step 1210 the procedure initiates a standby. If, however, the trade-off is favorable, then at step 1212 the position of the sun is determined relative to the sun and, photovoltaic array is re-aligned relative to ambient sunlight at step 1214. The procedure ends at step 1216.

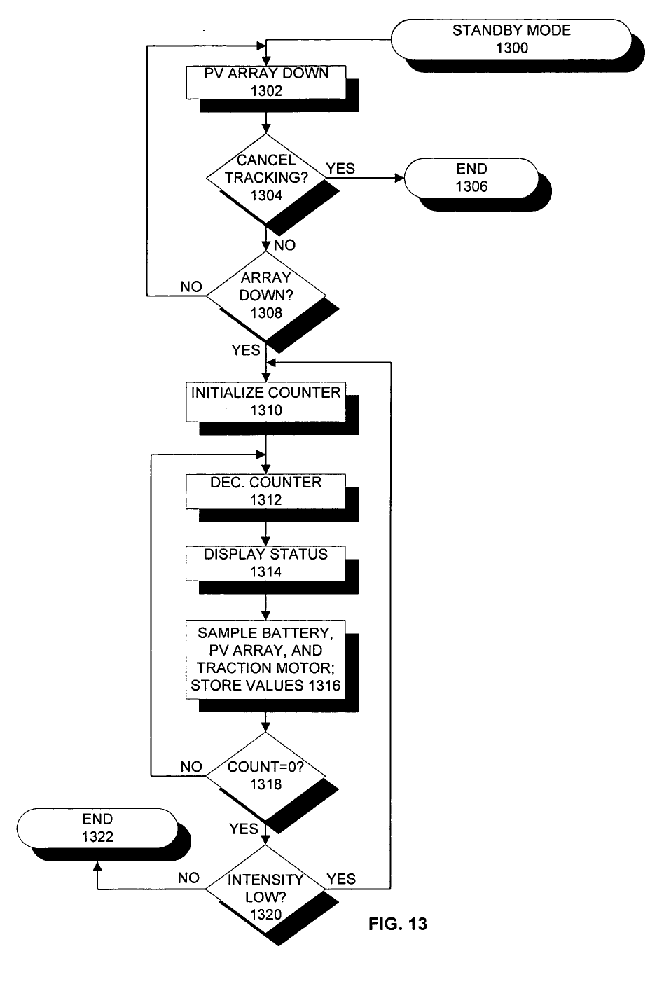

FIG. 13 provides a flowchart illustrating the steps of a standby procedure that can be used, according to one embodiment of the present invention, in conjunction with the tracking procedure previously described in connection with the powering of a vehicle using a re-chargeable battery and photovoltaic array. The initiation of the standby procedure begins at step 1300. In a stand-by mode, the photovoltaic array is lowered at step 1302 to a zero-degree angle, such that the photovoltaic array is flat or approximately parallel to a surface on which the vehicle is positioned. A determination is made at step 1304 as to whether to continue a tracking procedure so as to track the position of the sun relative to the vehicle. If so, the standby procedure terminates at step 1306. Otherwise, the standby procedure continues. If the photovoltaic array is determined at step 1308 to be in an elevated position, it is lowered, and the previous steps are repeated.

At step 1310, the standby procedure with the tracking activated continues with the initialization of a counter. The counter is subsequently decremented at step 1312 after a predetermined time interval. The status of the procedure is displayed on a display screen such as an LCD at step 1314 and at least one parameter or variable associated with the vehicle battery, vehicle motor, or the photovoltaic array is sampled and stored at step 1316. Steps 1312-1316 are repeated until the counter, having been decremented at successive time intervals, takes on a zero value at step 1318. When it is determined at step 1318 that the value of the counter is zero, the intensity of sunlight incident upon the photovoltaic array is determined. If it is determined at step 1320 that the intensity is low, the standby procedure continues and each of the preceding steps is repeated. If the intensity of sunlight exceeds a predetermined threshold, however, then the standby procedure terminates at step 1322. When the standby procedure terminates as a result of the intensity of sunlight exceeding the predetermined threshold, a procedure for aligning the photovoltaic array can be initiated so that the photovoltaic array can be aligned relative to ambient sunlight to thereby enhance the capture of solar energy from the sun.

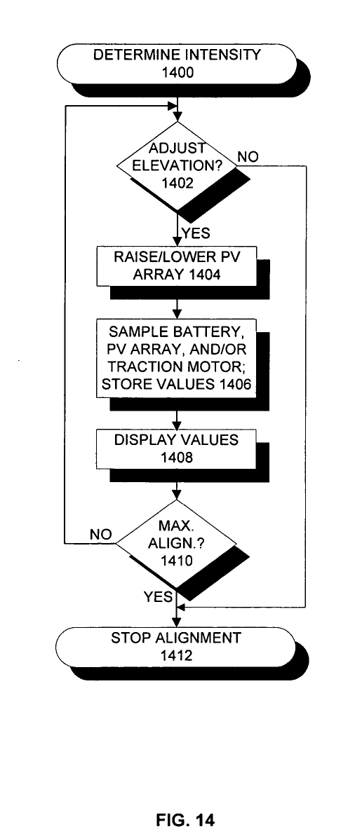

FIG. 14 provides a flowchart illustrative of a procedure for aligning a photovoltaic array relative to ambient sunlight in connection with powering a motor-driven vehicle using a re-chargeable battery and photovoltaic array. The intensity of sunlight is initially determined at step 1400. A subsequent decision is made at step 1402 as to whether the capture of solar energy can be enhanced by adjusting the alignment of the photovoltaic array relative to ambient sunlight. If so, then, according to one embodiment, one or more edges of the photovoltaic array are raised or lowered at step 1404 so as to cause the incidence of sunlight on the photovoltaic array to more closely approximate, or be at, a normal or orthogonal angle relative to the top surface of the photovoltaic array.

At least one parameter or variable associated with the vehicle battery, vehicle motor, or the photovoltaic array is subsequently sampled and stored at step 1406. At step 1408 at least one parameter or variable associated with the vehicle battery, vehicle motor, or the photovoltaic array can be displayed. A determination is made at step 1410 as to whether the resulting incidence of sunlight on the photovoltaic array is as closely approximate to or at a normal or orthogonal angle relative to a top surface of the photovoltaic array as can be achieved in the current environment. If not, the alignment procedure continues with the preceding steps being repeated. Otherwise, the alignment procedure terminates at step 1412. Once the alignment procedure terminates, an alignment standby procedure can be initiated.

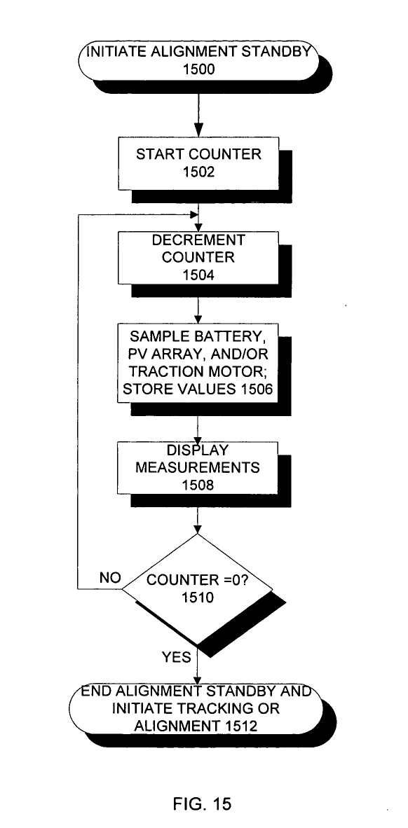

FIG. 15 illustrates the operative steps of an alignment standby procedure in connection with powering a motor-driven vehicle using a re-chargeable battery and photovoltaic array. The alignment standby procedure is initiated at step 1500 when the photovoltaic array is at a normal or orthogonal angle relative to a top surface of the photovoltaic array or as close to a normal or orthogonal angle as can be achieved under current circumstances. A counter is initialized and started at step 1502. The counter is decremented after a predetermined time interval at step 1504. At step 1506 at least one parameter or variable associated with the vehicle battery, vehicle motor, or the photovoltaic array is sampled and stored.

At least one value for a parameter or variable associated with the vehicle battery, vehicle motor, or the photovoltaic array is subsequently displayed at step 1508. If the counter takes on a non-zero value at step 1510, then the preceding steps are repeated. When, however, the counter takes on a zero value, the alignment standby procedure terminates. Upon termination, tracking of the position of the sun relative to the vehicle can resume. Additionally, an alignment procedure for aligning the photovoltaic array relative to ambient sunlight can be initiated upon termination of the alignment procedure.

As described above, various features of the present invention can be realized in hardware, software, or a combination of hardware and software. The same features can be realized in a centralized fashion in one computer system, or in a distributed fashion wherein different elements are spread across several interconnected computer systems. Any kind of computer system or other apparatus adapted for effecting the features or carrying out the methods described herein is suited. A typical combination of hardware and software can be a general purpose computer system with a computer program that, when being loaded and executed, controls the computer system such that it carries out the methods described herein.

Various features of the present invention also can be embedded in a computer program product, which comprises all the features enabling the implementation of the features and methods described herein, and which when loaded in a computer system is able to carry out these methods. A computer program in the present context refers to any expression, in any language, code or notation, of a set of instructions intended to cause a system having an information processing capability to perform a particular function either directly or after either or both of the following: a) conversion to another language, code or notation; b) reproduction in a different material form.

The present invention can be embodied in other forms without departing from the spirit or essential attributes thereof. Accordingly, reference should be made to the following claims, rather than to the foregoing specification, as indicating the scope of the invention.

That claimed is:

1. A self-propelled vehicle comprising:
a vehicle body;
a vehicle propulsion mechanism for propelling the vehicle body over a surface;
a vehicle motor carried by the vehicle body for driving the propulsion mechanism;
a battery carried by the vehicle body for supplying power to the vehicle motor; and
a photovoltaic powering system carried by the vehicle body, the photovoltaic powering system including
a movable platform connected to the vehicle body and comprising an array of at least on photovoltaic cell
a platform movement mechanism for moving the platform, and
a platform alignment module carried by the vehicle body, the platform alignment module connected to the platform movement mechanism for aligning the moveable platform relative to ambient sunlight.

2. The self-propelled vehicle of claim 1, wherein the photovoltaic powering system further includes a power point tracking (PPT) module connected to the array to thereby control energy transfers between the array and the battery so that the array operates at or close to a maximum power point.

3. The self-propelled vehicle of claim 1, wherein the photovoltaic powering system further includes a performance monitoring module connected to the battery for monitoring a charge level of the battery.

4. The self-propelled vehicle of claim 1, wherein the photovoltaic powering system further includes a performance monitoring module connected to the array for monitoring at least one of power delivered from the array to the vehicle motor and power delivered from the array to an external electrical device.

5. The self-propelled vehicle of claim 1, wherein the photovoltaic powering system further includes an inverter connected to the at least one photovoltaic cell, the inverter converting a DC current generated by the photovoltaic cell to an AC current deliverable to at least one of an external power grid and an external electrical device.

6. The self-propelled vehicle of claim 1, wherein the photovoltaic powering system further includes an electrical connector for providing an electrical connection between the array and an external device.

7. The self-propelled vehicle of claim 1, wherein the photovoltaic powering system further includes a critical tilt module for detecting when the moveable platform is aligned at an angle equal to or greater than a critical tilt angle, the critical tilt angle defining an angle beyond which the moveable platform is not tilted when the vehicle is being propelled over a surface.

8. The self-propelled vehicle of claim 1, wherein the photovoltaic powering system further includes an excess power delivery device connected to the battery for providing a conduit through which power can be delivered to at least one of an external electrical device and a power grid.

9. The self-propelled vehicle of claim 1, wherein the photovoltaic powering system further includes an excess power delivery device connected to the battery and having an on-board electrical inverter for converting a DC current to an AC current to thereby deliver AC-based power to at least one of an external electrical device and a power grid.

10. A photovoltaic powering system comprising:
a movable platform connected to a self-propelled vehicle and comprising an array of at least one photovoltaic cell;
a platform movement mechanism carried by the vehicle for moving the platform; and
a platform alignment module carried by the vehicle, the platform alignment module connected to the platform movement mechanism for aligning the moveable platform relative to ambient sunlight;
wherein the at least one photovoltaic cell converts ambient sunlight to energy that is supplied to a battery carried by the vehicle to thereby recharge the battery.

11. The photovoltaic powering system of claim 10, further comprising a power point tracking (PPT) module connected to the array to thereby control energy transfers between the array and the battery so that the array operates at or near a maximum power point.

12. The photovoltaic powering system of claim 10, further comprising an inverter connected to the at least one photovoltaic cell, the inverter converting a DC current generated by the photovoltaic cell to an AC current deliverable to at least one of an external power grid and an external electrical device.

13. The photovoltaic powering system of claim 10, further comprising an electrical connector for providing an electrical connection between the array and an external device.

14. The photovoltaic powering system of claim 10, further comprising a critical tilt module for detecting when the moveable platform is aligned at an angle equal to or greater than a critical tilt angle, the critical tilt angle defining an angle beyond which the moveable platform is not tilted when the vehicle moves over a surface.

15. The photovoltaic powering system of claim 10, further comprising an excess power delivery device connected to the battery for providing a conduit through which power can be delivered to at least one of an external electrical device and a power grid.

16. The photovoltaic powering system of claim 10, further comprising an excess power delivery device connected to the battery and having an on-board electrical inverter for converting a DC current to an AC current to thereby deliver AC-based power to at least one of an external electrical device and a power grid.

17. The photovoltaic powering system of claim 10, further comprising a plurality of docking stations and an external battery bank connected to the plurality of docking stations for exchanging power between at least two of the array, the external battery bank, and a power grid connected to the external battery bank.

18. The photovoltaic powering system of claim 17, further comprising an inverter connected to the external battery bank for converting a DC current to an AC current.

19. The photovoltaic powering system of claim 17, further comprising a monitor electrically connected to the external battery bank for monitoring the power exchange.

20. A method of generating and supplying power using solar energy, the method comprising:
automatically aligning an array of at least one photovoltaic cell relative to ambient sunlight, the array connected to a self-propelled vehicle;
converting the ambient sunlight to usable energy; and
supplying the usable energy to a battery carried by the vehicle to thereby recharge the battery if a charge associated with the battery is less than a predetermined threshold.

21. The method of claim 20, further comprising controlling energy transfers across an interface between the array and the battery so that the array operates at or close to a maximum power point.

22. The method of claim 20, further comprising monitoring at least one of monitoring a charge level of the battery, power delivered from the array to the vehicle, and power delivered from the array to an electrical device external to the vehicle

23. The method of claim 20, further comprising supplying excess power to at least one of an external electrical device and a power grid.

24. The method of claim 20, further comprising electrically connecting the array to a combined docking-and-powering station, the docking-and-powering station having a plurality of docking stations and an external battery bank comprising a plurality of interconnected batteries connected to the plurality of docking stations and to a separate power grid.

25. The method of claim 24, further comprising selectively conveying power among at least two the array, the external battery bank, and the power grid.
